(19) United States
(12) Patent Application Publication
(10) Pub. No.: US 2025/0093227 A1
(43) Pub. Date: Mar. 20, 2025

(54) MACHINE LEARNING BASED SYSTEM TO DETECT FLUID LEAKS IN AN ELECTRICAL APPARATUS

(71) Applicant: Eaton Intelligent Power Limited, Dublin (IE)

(72) Inventors: Bubathi Muruganantham, Pune (IN); Priyanka D. Jadhav, District Solapur (IN); Prasad Arvind Venikar, Pune (IN); Mugdha Vyankatesh Limaye, Pune (IN); Travis Vernon Spoone, Greenwood, SC (US); Mark Andre Faulkner, Greenwood, SC (US); Antonio Romero Oruga, Greenwood, SC (US)

(21) Appl. No.: 18/884,637

(22) Filed: Sep. 13, 2024

Related U.S. Application Data
(60) Provisional application No. 63/538,967, filed on Sep. 18, 2023.

(51) Int. Cl. G01M 3/40; G01R 31/62

(52) U.S. Cl. CPC G01M 3/40; G01R 31/62

(57) ABSTRACT

An electrical apparatus includes: a housing that defines an interior space configured to hold a fluid; and a control system configured to: obtain a measured temperature value of the fluid from a sensor; build a dataset of fault indicator values, where each fault indicator is a numerical value based on a temperature error, the temperature error is based on a difference between the measured temperature value of the fluid and an estimated temperature value of the fluid; generate one or more features from the dataset; apply a classifier to the one or more features to determine a fluid leak output; and determine whether a fluid leak condition exists in the electrical apparatus based on the fluid leak output.

### CROSS-REFERENCE TO RELATED APPLICATION

This application claims the benefit of U.S. Provisional Application No. 63/538,967, filed Sep. 18, 2023 and titled MACHINE LEARNING BASED SYSTEM TO DETECT FLUID LEAKS IN AN ELECTRICAL APPARATUS, which is incorporated herein by reference in its entirety.

### TECHNICAL FIELD

This disclosure relates to a machine learning based system to detect fluid leaks in an electrical apparatus.

### BACKGROUND

An electrical asset, such as transformer, may be used as part of an electrical system that distributes time-varying or alternating current (AC) electrical power. The electrical system may include other electrical assets, such as, for example, voltage regulators, inductors, transmission lines, and switches.

### SUMMARY

In one aspect, an electrical apparatus includes: a housing that defines an interior space configured to hold a fluid; and a control system configured to: obtain a measured temperature value of the fluid from a sensor; build a dataset of fault indicator values, where each fault indicator is a numerical value based on a temperature error, the temperature error is based on a difference between the measured temperature value of the fluid and an estimated temperature value of the fluid; generate one or more features from the dataset; apply a classifier to the one or more features to determine a fluid leak output; and determine whether a fluid leak condition exists in the electrical apparatus based on the fluid leak output.

Implementations may include one or more of the following features.

The control system also may be configured to access an electrical apparatus health status indicator, and the control system may be configured to determine whether the fluid leak condition exists based on the fluid leak output and the electrical apparatus health status indicator.

The control system may be configured to generate the one or more features from the dataset by applying a principle components analysis to the dataset, and the one or more features may include one or more principle components of the fault indicator values of the dataset. The control system may be configured to generate the one or more features from the dataset by applying a principle components analysis to the dataset, and the one or more features may include one or more principle components of the fault indicator values of the dataset.

The classifier may include a machine learning model. The machine learning model may include a neural network.

The electrical apparatus also may include one or more electrical windings in the interior space, and the control system may determine that the fluid leak condition exists when one or more of the plurality of fault indicators does not meet the associated fault specification and the electrical health status indicator indicates that a short is not present in the one or more electrical windings.

The electrical apparatus also may include one or more electrical windings in the interior space, and the control system may determine that the fluid leak condition does not exist when one or more of the plurality of fault indicators does not meet the associated fault specification and the electrical health status indicator indicates that a short is present in the one or more electrical windings.

The plurality of fault indicators may include: an average of the temperature error, a root mean square average of the temperature error, a mean average error of the temperature error, and a percent error of the temperature error.

The measured temperature of the fluid may include a temperature measurement of the fluid at fixed distance from a top of the interior space and the estimated temperature may be an estimate of the temperature of the fluid at the same location.

The electrical apparatus may be a transformer.

In another aspect, a method for determining if a fluid leak condition exists in an electrical apparatus includes: determining a temperature error based on a measured temperature of a fluid in the electrical apparatus and an estimated temperature of the fluid in the electrical apparatus; determining fault indicators based on the temperature error; extracting one or more features from the determined fault indicators; providing the one or more features to a classifier to determine a value of a fluid health indicator; analyze the value of the fluid health indicator to determine if a possible fluid leak condition exists; and if a possible fluid leak condition exists: determining whether an electrical fault condition exists, if an electrical fault condition does not exist, determining that the possible fluid leak condition is an actual fluid leak condition, and if an electrical fault condition exists, determining that no fluid leak condition exists.

Implementations may include one or more of the following features.

Extracting one or more features from the determined fault indicators may include performing principle component analysis on the fault indicators to extract one or more principle components.

The method also may include training the classifier prior to providing the one or more features to the classifier.

In another aspect, a monitoring system for an electrical apparatus includes: a temperature error module configured to determine a temperature error based on an estimated temperature of a fluid in an electrical apparatus and a measured temperature of the fluid in the electrical apparatus; a fault analysis module configured to determine a plurality of fault indicators based on the temperature error; a feature extraction block configured to determine a reduced dataset based on the plurality of fault indicators; a classifier block configured to determine a fluid leak output based on the reduced dataset; and a decision block configured to output a fluid leak indicator based on the fluid leak output.

In some implementations, the decision block is configured to output the fluid leak indicator based on the fluid leak output and an electrical apparatus health status indicator, where the electrical apparatus health status indicator relates to the presence of an electrical fault in the electrical apparatus and the fluid leak output relates to the presence of a fluid leak in the electrical apparatus.

Implementations of any of the techniques described herein may be a system, a method, or executable instructions stored on a machine-readable medium. The details of one or more implementations are set forth in the accompanying drawings and the description below. Other features will be apparent from the description and drawings, and from the claims.

### DRAWING DESCRIPTION

FIG. 1 is a block diagram of an example of a system.

FIG. 2 is a block diagram of another example of a system.

FIG. 3 is a block diagram of an example of the control scheme.

FIG. 4 is a flow chart of an example of a training process.

FIG. 5 is a flow chart of an example of a monitoring process.

FIG. 6 is a block diagram of an example of a fluid leak detection module.

FIG. 7 is a flow chart of an example of a process for determining whether a fluid is leaking from an electrical apparatus.

FIG. 8 is a flow chart of an example of a process for generating the fault indicators.

FIG. 9 is a flow chart of an example of a training process.

FIG. 10 shows an example of an artificial neural network.

FIGS. 11A-11D and 12 relate to experimental test results.

### DETAILED DESCRIPTION

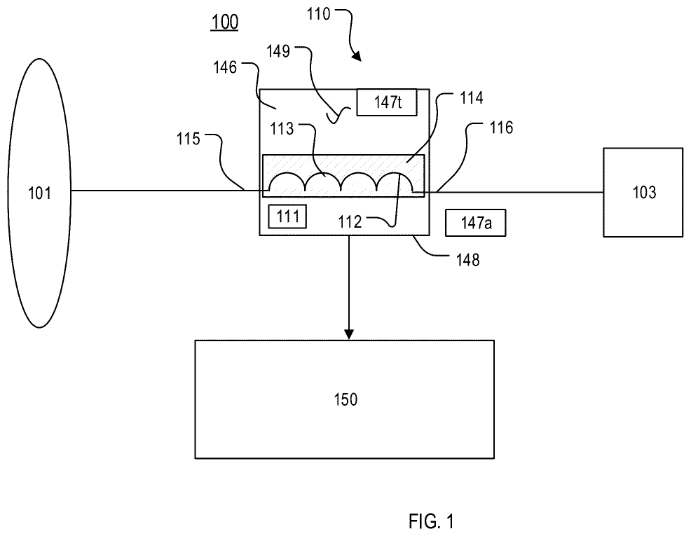

FIG. 1 is a block diagram of an example of a system 100 that includes an alternating current (AC) electrical power grid 101. A single phase is shown in FIG. 1 for simplicity. However, the power system 100 may be a multi-phase (for example, three-phase) power system. The electrical asset 110 is any type of electrical equipment that is configured for use in an AC electrical power system. For example, the electrical asset 110 may be a transformer, a voltage regulator, a network protector, or an inductor. The electrical asset 110 may be a three-phase electrical asset. The electrical power system 100 includes an electrical asset 110 and a monitoring system 150. The electrical asset 110 includes a housing 148 that defines an interior space 149 and a fluid 146 in the interior space 149. As discussed below, the monitoring system 150 determines whether a fluid leak condition exists in the electrical asset 110.

The fluid 146 provides thermal regulation (for example, cooling) and electrical insulation during operation of the electrical asset 110. A fluid leak condition exists when the fluid 146 leaks out of the interior space 149 or otherwise exits the interior space 149. When some or all of the fluid 146 exits the interior space 149, the electrical asset 110 may overheat, catch on fire, experience more shorts and/or other electrical conditions, and/or may have reduced overall performance. Furthermore, the fluid 146 may be corrosive or otherwise harmful to the area in the vicinity of the electrical asset 110.

One legacy approach to detecting fluid leaks in an electrical asset is to send a skilled technician to visually inspect the electrical asset based on the assumption that fluid leaks generally occur in specific areas of the electrical asset that are visible from the exterior of the asset, such as weld seams and/or a joint area of a flange. However, environmental conditions (for example, wind, rain, snow, ice, and sleet) may prevent routine visual inspection or make visual inspection impractical. Moreover, the location of the electrical asset also may hamper visual inspection. For example, the electrical asset may be underground, in a remote location, and/or in a dangerous location. Additionally, using a dedicated imaging device (for example, a visible, infrared or ultraviolet imaging sensor) to remotely monitor the exterior of the electrical asset requires expensive and complex equipment and data processing and is generally not practical for most applications.

Some other legacy approaches measure the fluid level in a transformer directly with, for example, an oil level gauge or other type of fluid level sensor. However, the fluid level in the electrical asset may vary with vibrations and/or thermal expansion during use. These effects reduce the accuracy of the gauge such that the gauge is not able to detect the small fluid leaks that are most efficient to correct. Moreover, such an approach may require additional sensors that are not already present in some electrical assets.

On the other hand, the monitoring system 150 uses an indirect approach to detect a fluid leak condition in the electrical asset 110 based on data that is already collected. The monitoring system 150 determines whether or not a fluid leak condition is present in the electrical asset 110 based on a thermal error calculation that uses data collected by the sensors 147a and 147t. In some implementations, the monitoring system 150 also uses a health status indicator of the electrical asset 110 to determine whether or not a fluid leak condition exists. The monitoring system 150 provides periodic or continuous monitoring of the electrical asset 110 and promotes early detection of fluid leaks and rapid correction of the fluid leaks. Moreover, because the monitoring system 150 uses data from sensors that are already installed in the electrical asset 110 (and are installed in most existing electrical assets), the monitoring system 150 may be used to retrofit existing electrical assets to provide leak detection for older electrical assets.

Before discussing the monitoring system 150 in greater detail, an overview of the AC power grid 101 and the electrical asset 110 is provided.

The AC power grid 101 is a three-phase power grid that operates at a fundamental frequency of, for example, 50 or 60 Hertz (Hz). The power grid 101 includes devices, systems, and components that transfer, distribute, generate, and/or absorb electricity. For example, the power grid 101 may include, without limitation, generators, power plants, electrical substations, transformers, renewable energy sources, transmission lines, reclosers and switchgear, fuses, surge arrestors, combinations of such devices, and any other device used to transfer or distribute electricity.

The power grid 101 may be low-voltage (for example, up to 1 kilovolt (kV)), medium-voltage or distribution voltage (for example, between 1 kV and 35 kV), or high-voltage (for example, 35 kV and greater). The power grid 101 may include more than one sub-grid or portion. For example, the power grid 101 may include AC micro-grids, AC area networks, or AC spot networks that serve particular customers. These sub-grids may be connected to each other via switches and/or other devices to form the grid 101. Moreover, sub-grids within the grid 101 may have different nominal voltages. For example, the grid 101 may include a medium-voltage portion connected to a low-voltage portion through a distribution transformer. All or part of the power grid 101 may be underground.

The load 103 may be any device that uses, transfers, or distributes electricity in a residential, industrial, or commercial setting, and the load 103 may include more than one device. For example, the load 103 may be a motor, an uninterruptable power supply, or a lighting system. The load 103 may be a device that connects the electrical asset 110 to another portion of the power grid 101. For example, the load 103 may be a recloser or switchgear, another transformer, or a point of common coupling (PCC) that provides an AC bus for more than one discrete load. The load 103 may include one or more distributed energy resources (DER). A DER is an electricity-producing resource and/or a controllable load. Examples of DER include, for example, solar-based energy sources such as, for example, solar panels and solar arrays; wind-based energy sources, such as, for example wind turbines and windmills; combined heat and power plants; rechargeable sources (such as batteries); natural gas-fueled generators; electric vehicles; and controllable loads, such as, for example, some heating, ventilation, air conditioning (HVAC) systems and electric water heaters.

The electrical asset 110 has a rated load, which is determined from the nominal voltage output of the electrical asset 110 at the maximum deliverable current that the electrical asset 110 is designed to conduct. The rated load may be expressed in units of volt-amperes (VA). The rated load may be included on a nameplate 111 of the electrical asset 110 and/or otherwise associated with the electrical asset 110. The electrical asset 110 is overloaded when the rated load is exceeded. The amount of overloading may be characterized relative to the rated load using a load factor, which is the ratio of the present load to the rated load. For example, operating the electrical asset 110 at the rated load is a load factor of 1, and operating the electrical asset such that it operates at a volt-ampere amount that is 10% greater than the rated load is a load factor of 1.1.

The housing 148 of the electrical asset 110 may be any solid, durable material, such as, for example, steel. The housing 148 is sealed and the interior space 149 contains the fluid 146. The fluid 146 may be, for example, a gas such as air, or a liquid such as oil. The fluid 146 may be an electrically insulating liquid, such as, for example, mineral oil, petroleum oil, vegetable oil, and/or synthetic fluids; or an electrically insulating gas.

The electrical asset 110 also includes a sensor 147t in the interior space 149 and a sensor 147a exterior to the housing 148. The sensors 147t and 147a are thermal sensors that measure, respectively, a temperature in the interior space 149 and an ambient temperature of the environment that surrounds the electrical asset 110. The sensors 147t and the sensor 147a provide data to the monitoring system 150.

The electrical asset 110 includes a winding 112 in the interior space 149. The electrical asset 110 has a first side 115 and a second side 116. In the example of FIG. 1, the first side 115 is electrically connected to an AC power grid 101 and the second side 116 is electrically connected to a load 103. Electrical power from the AC power grid 101 is delivered to the load 103 through the winding 112. In some implementations, the electrical asset 110 is configured to allow bi-directional power flow such that electrical power is also delivered from the load 103 to the grid 101 through the winding 112. In implementations in which the electrical asset 110 is a transformer, the first side 115 and the second side 116 may be referred to as the primary side 115 and the secondary side 116, respectively. The first side 115 may be referred to as a input side 115 and the second side 116 may be referred to as an output side 116.

The winding 112 is made of an electrically conductive material, such as a metal, and is shaped into a coil that includes turns 113. In the example shown in FIG. 1, the winding 112 includes many turns but only one turn is labeled for simplicity. The winding 112 may have any configuration and arrangement that is suitable for the application. For example, the winding 112 may be a copper wire wound in a helix shape or a copper wire wound around a core, such as a ferromagnetic annulus.

The electrical asset 110 also includes insulation 114 (shown with diagonal striped shading in FIG. 1). The insulation 114 electrically insulates the turns 113 from each other and also may electrically insulate the winding 112 from other parts of the electrical asset 110. The insulation 114 also may mechanically support the winding 112 and/or protect the winding 112 from contamination.

The insulation 114 may be directly attached to the winding 112. For example, the insulation 114 may be an electrically insulating coating that is applied to the outer surface of the winding 112. Examples of this type of insulation 114 include, without limitation, resin, epoxy, varnish, and polymer coatings or claddings. The insulation 114 may be an electrically insulating material that is separate from the winding 112 and does not necessarily make contact with the winding 112. Examples of this type of insulation 114 include, without limitation, physical barriers, such as, for example, clamps, boards, and/or spacers made of electrically insulating material, such as, for example, polymer foam or polymer sheets. The insulation 114 may include a combination of such materials. For example, the winding 112 may be coated with a resin and surrounded by an electrically insulating hardened foam.

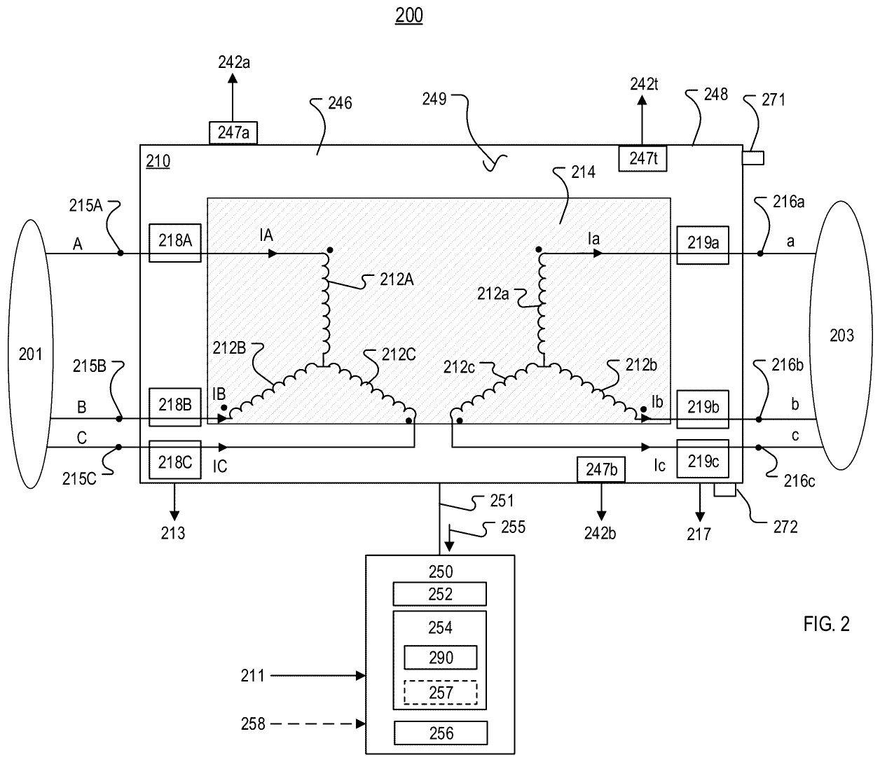

FIG. 2 is a block diagram of a system 200. The system 200 includes an electrical asset 210 and a monitoring system 250. The electrical asset 210 is a three-phase, wye-wye connected transformer that is cooled with a fluid 246, such as, for example, a synthetic or natural oil. Other configurations of the electrical asset 210 are possible, and the three-phase, wye-wye connected transformer is provided as an example.

The transformer 210 includes a housing 248 that defines an interior region 249. The interior region 249 contains the fluid 246. The transformer 210 also includes a fluid inlet 271 and a fluid outlet 272, both of which are in fluid communication with the interior region 249. The fluid 246 is intentionally introduced into the interior region 249 through the fluid inlet 271 and is intentionally removed from the interior region 249 through the fluid outlet 272.

The transformer 210 includes thermal sensors 247t, 247b in the interior region 249. The thermal sensors 247t and 247b may be any type of thermal sensor, such as, for example, a thermocouple. The thermal sensor 247t produces a top fluid temperature indication 242t, which is an indication of the temperature of the fluid 246 at or near the inlet 271.

A thermal sensor 247a is positioned to measure the ambient temperature in the environment that is exterior to the interior region 249. For example, the thermal sensor 247a may be mounted on the housing 248 or next to the exterior of the housing 248. In some implementations, the thermal sensor 247a is placed in the vicinity of the housing 248. For example, the thermal sensor 247a may be positioned at a distance of one (1) meter or more from the exterior of the housing 248. The thermal sensor 247a produces an ambient temperature indication 242b, which is an indication of the temperature of the environment that surrounds the transformer 210. The thermal sensor 247a may be any kind of sensor that is capable of measuring temperature. For example, the thermal sensor 247a may be a thermocouple or a thermometer. In some implementations, the thermal sensor 247a is part of a weather station that produces meteorological data in addition to providing temperature data.

The transformer 210 includes two windings per phase in the interior region 249, as follows: a primary winding 212A and a secondary winding 212a in the A phase, a primary winding 212B and a secondary winding 212b in the B phase, and a primary winding 212C and a secondary winding 212c in the C phase. The transformer 210 also includes electrical insulation 214 (show in gray diagonal striped shading) that protects the primary and secondary windings. The electrical asset 210 has first nodes 215A, 215B, 215C and second nodes 216a, 216b, 216c. The first nodes 215A, 215A, 215C are electrically connected to phases A, B, C of an AC power grid 201. The AC power grid 201 distributes AC current that has a fundamental frequency. The second nodes 216a, 216b, 216c are connected to phases a, b, c of a load 203.

A primary AC current IA, IB, IC flows in each respective first node 215A, 215B, 215C. A secondary AC current Ia, Ib, Ic flows from in each respective second node 216a, 216b, 216c. The transformer 210 may be used to increase or decrease the amplitude of the secondary currents and voltages relative to the primary currents and voltages. When the number of turns in the primary winding 212A, 212B, 212C is greater than the number of turns in the respective secondary winding 212a, 212b, 212c, the amplitude of the secondary current Ia, Ib, Ic is greater than the amplitude of the respective primary current IA, IB, IC. When the number of turns in the primary winding 212A, 212B, 212C is less than the number of turns in the respective secondary winding 212a, 212b, 212c, the amplitude of the secondary current Ia, Ib, Ic is smaller than the amplitude of the respective primary current IA, IB, IC.

The transformer 210 also includes sensors 218A, 218B, 218C that measure one or more electrical properties at the first nodes 215A, 215B, 215C and sensors 219a, 219b, 219c that measure one or more electrical properties at the second nodes 216a, 216b, 216c. For example, each of the sensors 218A, 218B, 218C, 219a, 219b, 219c may measure current, voltage, and/or power at the respective nodes 215A, 215B, 215C, 216a, 216b, 216c. The sensors 218A, 218B, 218C, 219a, 219b, 219c may be any kind of electrical sensor, for example, current transformers (CTs), Rogowski coils, power meters, and/or potential transformers (PT).

The sensors 218A, 218B, 218C produce an indication 213, and the sensors 219a, 219b, 219c produce an indication 217. The indications 213 and 217 include data that represent measured values. For example, the indications 213 and 217 may include sets of numerical values that are each associated with a time stamp, where each set includes three measured values that represent an instantaneous value of an electrical property at one of the first nodes or one of the second nodes. Although the indications 213 and 217 are shown in the example of FIG. 2, other implementations are possible. For example, in some implementations, each sensor 218A, 218B, 218C, 219a, 219b, 219c produces a separate indication.

The monitoring system 250 receives measured data 255 as an input. The measured data 255 includes the indications 213 and 217, the top fluid temperature indication 242t, the bottom fluid temperature indication 252b, and the ambient temperature indication 242b.

The monitoring system 250 includes an electronic processing module 252, an electronic storage 254, and an input/output (I/O) interface 256. The electronic processing module 252 includes one or more electronic processors, each of which may be any type of electronic processor and may or may not include a general purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 254 is any type of electronic memory that is capable of storing data and instructions in the form of computer programs or software, and the electronic storage 254 may include volatile and/or non-volatile components. The electronic storage 254 and the processing module 252 are coupled such that the processing module 252 can access or read data from and write data to the electronic storage 254.

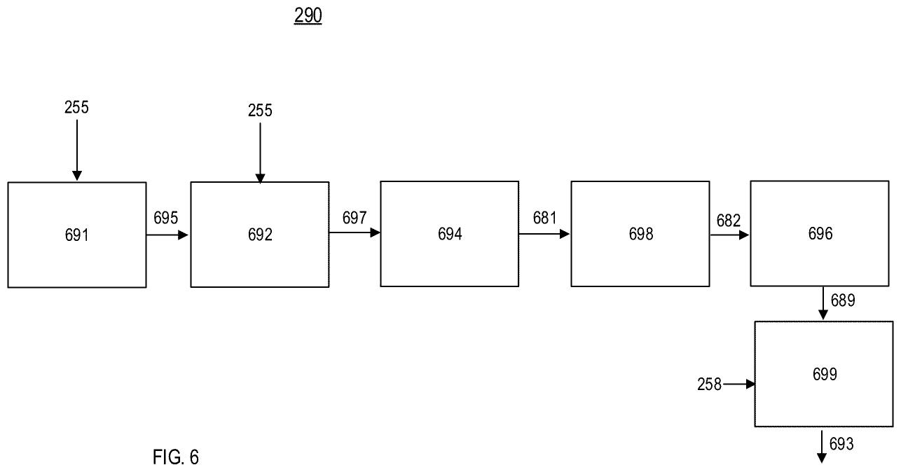

The electronic storage 254 stores executable instructions, for example, as a computer program, logic, or software, that cause the processing module 252 to perform various operations. The electronic storage 254 includes executable instructions that implement a fluid leak detection module 290. The fluid leak detection module 290 determines a temperature error and uses the temperature error to determine whether or not a fluid leak condition exists in the transformer 210. The temperature error may be determined based on the top fluid temperature indication 242t and an estimate of the top fluid temperature. FIGS. 6-10 discuss the fluid leak detection module 290 in more detail.

In some implementations, the fluid leak detection module 290 uses an electrical apparatus health indicator 258, in addition to the temperature error, to determine whether or not a fluid leak condition exists in the transformer 210. The electrical apparatus health indicator 258 is a value or flag that provides information about the health of the transformer 210. The electrical apparatus health indicator 258 may be a binary value that indicates whether or not an electrical fault (for example, a short) is present in any of the windings 212A, 212B, 212C, 212a, 212b, 212c. In some implementations, the electrical apparatus health status indicator 258 is entered into the monitoring system 250 through the I/O interface 256.

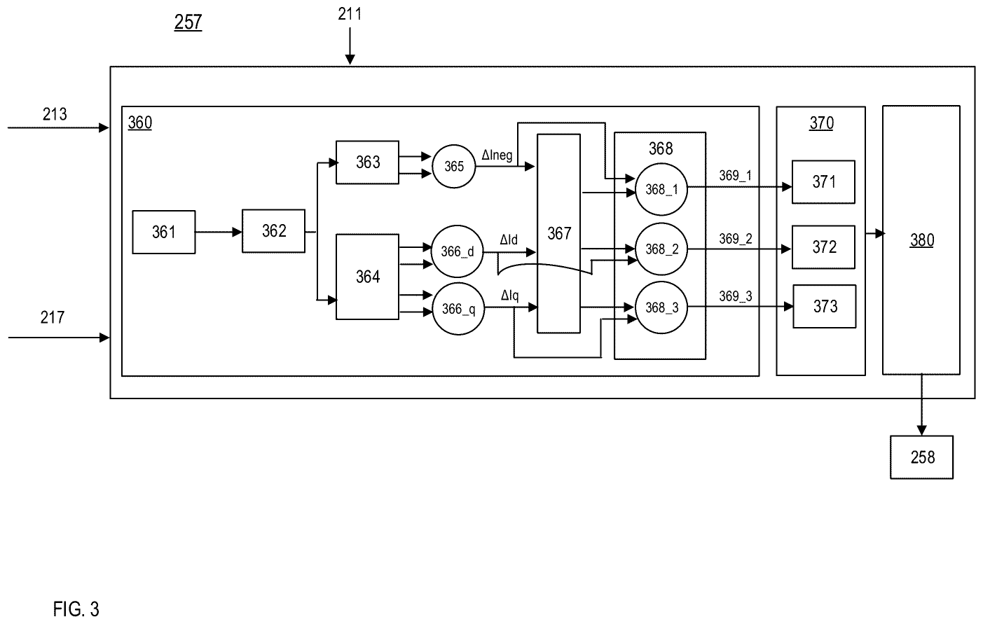

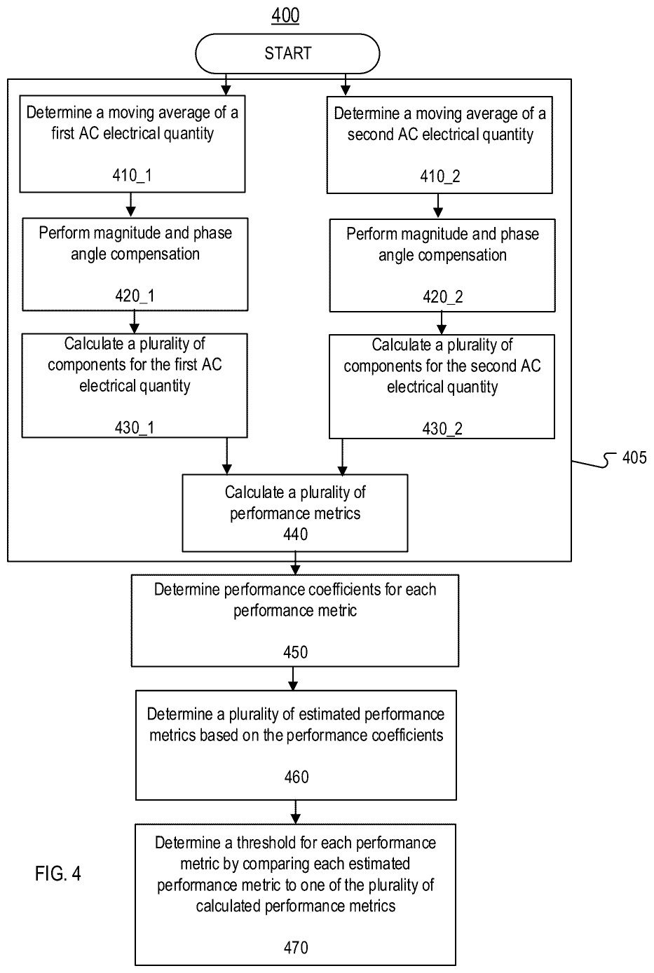

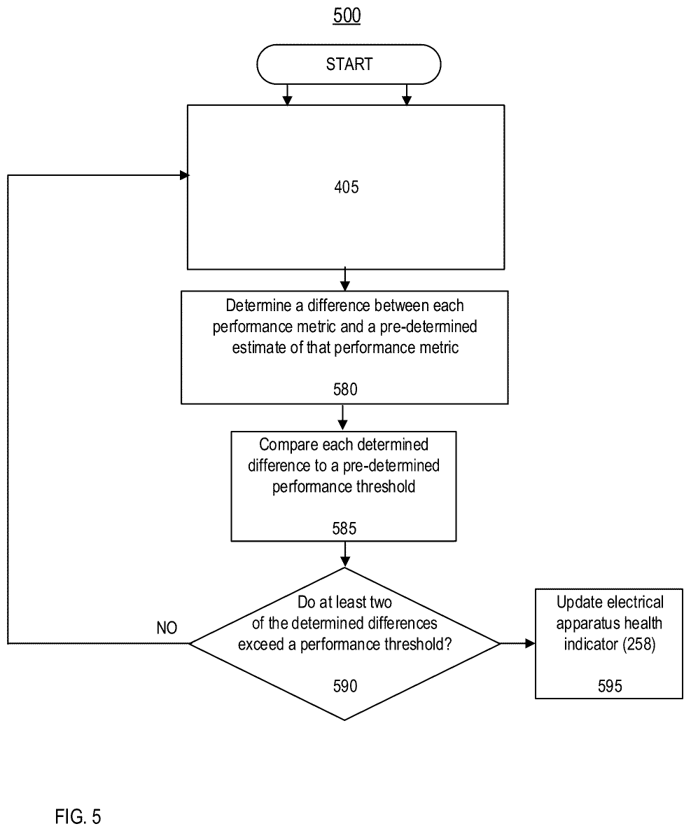

In some implementations, the electrical apparatus health status indicator 258 is calculated based on the nameplate information 211 using a control scheme 257 that is stored on the electronic storage 254 as executable instructions. The control scheme 257 includes executable instructions that cause the processing module 252 to analyze information and data from the transformer 210 to determine performance metrics for the transformer 210 in a training or commissioning stage. The determined performance are stored on the electronic storage 254 and/or output via the I/O interface 256. The control scheme 257 also includes executable instructions that cause the processing module 252 to apply the determined performance metrics to later-collected data from the transformer 210 in a monitoring stage to determine whether or not a potential failure exists in the transformer 210. Details about an example of an implementation of the control scheme 257 are discussed with respect to FIG. 3. An example of the training stage is provided with respect to FIG. 4. An example of the monitoring stage is provided with respect to FIG. 5.

The instructions also include instructions that, when executed by the processing module 252, implement various transformations and analysis techniques. For example, the electronic storage 254 stores executable instructions that implement the Park transformation, the Clarke transformation, the inverse Park transformation, and/or the inverse Clarke transformation. The instructions also may include instructions that cause the I/O interface 256 to produce a perceivable alarm or alert when a potential failure exists in the transformer 210.

The electronic storage 254 also may store information about the transformer 210. For example, the electronic storage 254 may store nameplate information 211. The nameplate information 211 may include, for example, the rated temperature of the insulation 214 (or the critical hotspot temperature limit); the rated load of the transformer 210; the number of turns on the windings winding 212A, 212B, 212C, 212a, 212b, 212c; a voltage and/or current rating of the transformer 210; a heat capacity of the material of the windings 212A, 212B, 212C, 212a, 212b, 212c; an identifier or flag that indicates the electrical configuration of the transformer 210; and/or an arrangement of the bushings on the transformer 210. The critical hotspot temperature limit is the highest temperature that the insulation 214 is designed to tolerate. The nameplate information 211 is loaded onto the electronic storage 254 via the I/O interface 256. For example, an operator may enter the nameplate information 211 while the transformer 210 is in the field. In another example, the manufacturer of the transformer 210 may add or edit the nameplate information 211 via the I/O interface 256.

The I/O interface 256 is any interface that allows a human operator, another electronic device, and/or an autonomous process to interact with the monitoring system 250. The I/O interface 256 may include, for example, a display (such as a liquid crystal display (LCD)), a keyboard, audio input and/or output (such as speakers and/or a microphone), visual output (such as lights, light emitting diodes (LED)) that are in addition to or instead of the display, serial or parallel port, a Universal Serial Bus (USB) connection, and/or any type of network interface, such as, for example, Ethernet. The I/O interface 256 also may allow communication without physical contact through, for example, an IEEE 802.11, Bluetooth, or a near-field communication (NFC) connection. The monitoring system 250 may be, for example, operated, configured, modified, or updated through the I/O interface 256.

The I/O interface 256 also may allow the monitoring system 250 to communicate with systems external to and remote from the monitoring system 250 and the transformer 210. For example, the I/O interface 256 may include a communications interface that allows communication between the monitoring system 250 and a remote station (not shown), or between the monitoring system 250 and a separate electrical apparatus (such as another transformer) using, for example, the Supervisory Control and Data Acquisition (SCADA) protocol or another services protocol, such as Secure Shell (SSH) or the Hypertext Transfer Protocol (HTTP). The remote station may be any type of station through which an operator is able to communicate with the monitoring system 250 without making physical contact with the monitoring system 250. For example, the remote station may be a computer-based work station, a smart phone, tablet, or a laptop computer that connects to the monitoring system 250 via a services protocol or a telephone system, or a remote control that connects to the monitoring system 250 via a radio-frequency signal. The monitoring system 250 may communicate information to an external device through the I/O interface 256.

As discussed above, in some implementations, the leak detection module 290 uses the health status indicator 258 of the transformer 210 in addition to the temperature error to determine whether or not a fluid leak condition exists in the transformer 210. FIGS. 3-5 relate to an example of calculating the health status indicator 258 based on electrical data measured from the transformer 210. FIGS. 6-10 relate to determining whether or not a leak condition exists in the transformer 210.

FIG. 3 is a block diagram of an implementation of the control scheme 257. The control scheme 257 is stored on the electronic storage 254 as executable instructions. The control scheme 257 is discussed with respect to the transformer 210 but may be used with any three-phase electrical asset.

The control scheme 257 includes a commissioning block 360, a training block 370, and an assessment block 380. The commissioning block 360 determines performance metrics. The training block 370 determines thresholds for the transformer 210 based on the performance metrics. The assessment block 380 applies the thresholds to determine the electrical asset health status indicator 258. In the example of FIGS. 3-5, the health status indicator 258 indicates whether a potential failure exists in the transformer 210. The control scheme 257 is discussed with respect to the transformer 210 but may be used with any three-phase electrical asset.

The control scheme 257 receives the indications 213 and 217 and the nameplate information 211 as inputs. In the example discussed below, the indications 213 and 217 include data regarding current flow in the primary and secondary nodes of the transformer 210. The indication 213 includes a value for the measured current in each of the nodes 215A, 215B, 215C. The indication 217 includes a value for the measured current in each of the nodes 216a, 216b, 216c.

The commissioning block 360 includes a pre-conditioning block 361, a compensation block 362, a symmetrical components calculation block 363, a transformation block 364, a fit estimation block 367, and an assessment block 368.

The pre-conditioning block 361 receives the indications 213 and 217 and determines a moving average of the current values in each indication 213 and 217. The pre-conditioning block 361 acts as a filter to remove or reduce noise and measurement errors that may be introduced by the sensors 218A, 218B, 218C, 219a, 219b, and/or 219c. Other filtering techniques may be used to reduce or remove the noise and measurement errors. Moreover, although the pre-conditioning block 361 improves the performance of the control scheme 257, the commissioning block 360 may be implemented without the pre-conditioning block 361.

The characteristics of the moving average are stored on the electronic storage 254 and/or entered into the monitoring system 250 via the I/O interface 256. The characteristics specify how many values are used in the moving average and/or how long of a period over which current samples are collected. For example, the pre-conditioning block 361 may perform a moving average of 100, 200, 500, 1000, or more samples.

The pre-conditioning block 361 produces two outputs: a moving average of the primary current (Ip_ave) based on the data in the indication 213 and a moving average of the secondary current (IS_ave) based on the data in the indication 217. The moving averages Ip_ave and IS_ave output by the pre-conditioning block 361 are vector values that include an average amplitude and an average phase angle for each phase A,B,C.

The compensation block 362 receives the outputs (Ip_ave and IS_ave) of the pre-conditioning block 361. The compensation block 362 performs magnitude and phase compensation on Ip_ave and IS_ave such that Ip_ave and IS_ave may be compared to each other without introducing errors. For example, the compensation block 362 may compensate the amplitude values in Ip_ave to be comparable to or to be normalized as the amplitude values in IS_ave. The compensation block 362 may compensate the amplitude values in Ip_ave to be the same as the amplitude values in IS_ave, or the compensation block 362 may compensate the amplitude values in Ip_ave to be within a threshold difference of the amplitude values in IS_ave. The specific implementation of the compensation block 362 depends on the configuration of the monitored asset (the transformer 210 in this example). The compensation block 362 produces two output vectors: the compensated average primary current vector (Ip_ave_comp) and the compensated average secondary current vector (IS_ave_comp).

Any magnitude and phase angle compensation technique may be implemented in the compensation block 362. For example, the magnitude may be compensated according to the transformer ratio (for example, the number of turns in a first primary winding of the transformer to the number of turns in a second primary winding of the transformer). The phase may compensated by rotating by the phase shift of the transformer.

The symmetrical components calculation block 363 and the transformation block 364 receive the vectors output by the compensation block 362. The symmetrical components calculation block 363 calculates the negative sequence current components. A three-phase system (such as the system 200) may be described by three phasors: (i) a positive sequence that has the same phase sequence as the system 200, (ii) a negative sequence that has a reverse phase sequence, (iii) and a zero sequence in which the phasors are in phase with each other. This approach converts three unbalanced phases into three independent source and simplifies asymmetrical fault analysis.

The symmetrical components calculation block 363 determines the negative sequence component Ip_neg (or Ī_{P_negative}) of the primary current from the compensated primary current vector (Ip_ave_comp). The symmetrical components calculation block 363 also determines the negative sequence component Is_neg (or Ī_{S_negative}) of the secondary current from the compensated secondary current vector (Is_ave_comp). The determination of the negative sequence current components is discussed next, with the negative sequence current components shown in Equations (3a) and (3b).

During a healthy condition of the transformer 210, the primary and secondary currents are related as:

$$[ \begin{matrix}\overline{{I}_{A}} \\ \overline{{I}_{B}} \\ \overline{{I}_{C}}\end{matrix} ] = [ \begin{matrix}{\overline{I}}_{A n l} \\ {\overline{I}}_{B n l} \\ {\overline{I}}_{C n l}\end{matrix} ] + [ \begin{matrix}{\overline{I}}_{a} \\ {\overline{I}}_{b} \\ {\overline{I}}_{c}\end{matrix} ] , \qquad Equation ( 1 )$$

where Ī_{A}, Ī_{B}, Ī_{C} are the are the primary A-phase, B-phase, and C-phase current vectors, respectively (collectively Ī_{P}); Ī_{Anl}, Ī_{Bnl}, Ī_{Cnl} are the no-load components of the A-phase, B-phase, and C-phase current vectors, respectively (collectively Īₙₗ); and Īₐ, Ī_{b}, Ī_{c} are the secondary a-phase, b-phase, and c-phase current vectors, respectively (collectively Ī_{S}). In this example, Ī_{P} is the compensated primary current vector (Ip_ave_comp) and Ī_{S} is the compensated secondary current vector (Is_ave_comp), both of which are output by the compensation block 362. Equation (1) may be rewritten as Equation (2):

$${\overline{I}}_{P} = {\overline{I}}_{n l} + {\overline{I}}_{S} , \qquad Equation ( 2 )$$

Ī_{P} are the primary current vectors, Īₙₗ are the no-load current vectors, and Ī_{S} are the secondary current vectors. Equation (2) is multiplied by A, where A=⅓[1 a² a] to produce Equations (3a) and (3b):

$$\frac{1}{3} [ \begin{matrix}1 & {a}^{2} & a\end{matrix} ] [ {\overline{I}}_{P} ] = \frac{1}{3} [ \begin{matrix}1 & {a}^{2} & a\end{matrix} ] [ {\overline{I}}_{n l} ] + \frac{1}{3} [ \begin{matrix}1 & {a}^{2} & a\end{matrix} ] [ {\overline{I}}_{S} ] \qquad Equation ( 3 a )$$

$${\overline{I}}_{P \_ negative} = {\overline{I}}_{nl \_ negative} + {\overline{I}}_{S \_ negative} \qquad Equation ( 3 b ) ,$$

where Ī_{P_negative} is the primary negative sequence current component and Ī_{S_negative} is the secondary negative sequence current component. The primary and secondary negative sequence current components are output by the symmetrical components calculation block 363.
For a healthy condition (when the transformer 210 does not have a potential failure), the vector difference of the primary current vector (Ī_{P}) and the secondary current vectors (Ī_{S}) is the vector difference of the negative sequence of no-load current, as shown in Equations (4a) and (4b):

$${\overline{Δ I}}_{negative} = {\overline{I}}_{nl \_ negative} = {\overline{I}}_{P \_ negative} - {\overline{I}}_{S \_ negative} \qquad Equation ( 4 a )$$

$${\overline{Δ I}}_{2} = {\overline{I}}_{P 2} - {\overline{I}}_{S 2} = {\overline{I}}_{n l 2} . \qquad Equation ( 4 b )$$

On the other hand, for a faulty condition with N_{f} turns and fault resistance of R_{f}, the A-phase current can be represented as:

$${\overline{I}}_{A f} = {\overline{I}}_{A n l f} + {\overline{I}}_{a} \qquad Equation ( 5 )$$

where,
Ī_{Anlf}=A-phase no-load current during fault; and

$${\overline{I}}_{A n l f} = {\overline{I}}_{A n l} + {\overline{I}}_{f} \frac{{N}_{f}}{N} \qquad Equation ( 6 )$$

where, Ī_{f}=fault current through the loop N=total number of turns on the faulted winding. The value of N is known from the nameplate information 211.
From Equations (2), (5) and (6), for fault condition:

$${\overline{I}}_{P f} = {\overline{I}}_{n l f} + {\overline{I}}_{S} \qquad Equation ( 7 a )$$

$${\overline{I}}_{n l f} = {\overline{I}}_{n l} + {\overline{I}}_{f}^{′} . \qquad Equation ( 7 b )$$

Pre-multiplying Equation (7a) by A and rearranging,

$${\overline{I}}_{Pf \_ negative} = {\overline{I}}_{nl \_ negative} + {\overline{I}}_{f \_ negative} + {\overline{I}}_{S \_ negative} \qquad Equation ( 8 a )$$

$${\overline{I}}_{Pf 2} = {\overline{I}}_{nl 2} + {\overline{I}}_{f 2} + {\overline{I}}_{S 2} \qquad Equation ( 8 b )$$

Therefore, when a potential fault exists, the vector difference of the primary and secondary negative sequence current (Δ̅I̅_{negative}) represents the vector of the negative sequence of no-load current with an additional component of unbalance due to fault current, as shown in Equation (9):

$${\overline{Δ I}}_{negative} = {\overline{I}}_{nl \_ negative} + {\overline{I}}_{f \_ negative} = {\overline{I}}_{Pf \_ negative} - {\overline{I}}_{S \_ negative} \qquad ( 9 )$$

The symmetrical components calculation block 363 multiples the primary current vector (Ip_ave_comp) by the matrix A to determine the primary negative sequence current component (Ī_{P_negative}) and the secondary current vector (Is_ave_comp) by the matrix A to determine the secondary negative sequence current component (Ī_{S_negative}). As noted above, the output of the symmetrical components calculation block 363 are the vectors Ī_{P_negative} and Ī_{S_negative}.

The outputs of the symmetrical components calculation block 363 are provided to a comparator 365. The comparator 365 performs a subtraction or difference operation and outputs the vector difference (Δ̅I̅_{negative}) of the primary negative sequence current component and the secondary negative sequence current component. The negative sequence vector difference (Δ̅I̅_{negative}) is one of the performance metrics.

The commissioning block 360 also includes the transformation block 364, which determines the d-axis and q-axis components of each of the primary current vector (Ip_ave_comp) and the secondary current vector (Is_ave_comp) output by the compensation block 362. The transformation block 364 implements an abc to dq transformation via the Clarke transformation, which converts three-phase AC quantities to orthogonal components in a two-dimensional stationary αβ reference frame, and the Park transformation, which converts the orthogonal components in the stationary αβ reference frame into d-axis and q-axis components. Together, the d-axis and the q-axis form a rectangular d-q coordinate system that rotates synchronously with a AC quantity. In this example, the AC quantity are the AC primary current vector (Ip_ave_comp) and the AC secondary current vector (Is_ave_comp). The Clark transformation is shown in Equation (10):

$${i}_{αβ} = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ] [ \begin{matrix}{i}_{a} \\ {i}_{b} \\ {i}_{c}\end{matrix} ] , \qquad Equation ( 10 )$$

where each of ia, ib, ic is a current in the primary current vector (Ip_ave_comp) or the secondary current vector (Is_ave_comp), and i_{αβ} is a vector that includes a component along the α axis and a component along the β axis. The Park transformation is shown in Equation (11):

$${i}_{dq} = [ \begin{matrix}cos ( θ ) & sin ( θ ) \\ - sin ( θ ) & cos ( θ )\end{matrix} ] [ \begin{matrix}{i}_{α} \\ {i}_{β}\end{matrix} ] , \qquad Equation ( 11 )$$

where i_{dq} is a vector that includes a component along the d axis and a component along the q axis, and θ is the rotation of the AC quantity.

Similar to the discussion above related to the negative sequence current, for the d-axis and q-axis components it is observed that,

$${\overline{Δ I}}_{d - axis} = {\overline{I}}_{Pf \_ d - axis} - {\overline{I}}_{S \_ d - axis} = {\overline{I}}_{nl \_ d - axis} + {\overline{I}}_{fd - axis} , and \qquad Equation ( 12 )$$

$${\overline{Δ I}}_{q - axis} = {\overline{I}}_{Pf \_ q - axis} - {\overline{I}}_{S \_ q - axis} = {\overline{I}}_{nl \_ q - axis} + {\overline{I}}_{fq - axis} . \qquad Equation ( 13 )$$

In other words, the vector difference of the d-axis current components represents the vector of the negative sequence no-load d-axis current with an additional component of unbalance due to fault current, and the vector difference of the q-axis current components represents the vector of the negative sequence no-load q-axis current with an additional component of unbalance due to fault current.

Equations (9), (12), and (13) indicate that turn-by-turn failure (or some other failure) in one or more of the windings 212A, 212B, 212C, 212a, 212b, 212c results in unbalanced terminal currents and results in higher differential currents (the additional component of unbalance). In other words, an increase in differential current is an indication of a developing fault condition or potential failure. Moreover, because the increase in the differential current is present in the negative sequence currents and the d-axis and q-axis components, all three of these differential quantities may be used as metrics to determine whether a potential fault or failure exists in the transformer 210. Using more than one metric increases the accuracy of the determination as compared to an approach that uses one differential quantity or one performance metric.

Returning to the transformation block 364, the d-axis components of the primary and secondary current are provided as inputs to a comparator 366_d and the q-axis components of the primary and secondary current are provided as inputs to a comparator 366_q. The comparator 366_d compares the d-axis component of the primary current to the d-axis component of the secondary current and outputs the vector difference as Δ̅I̅_{d-axis}. The comparator 366_q compares the q-axis component of the primary current to the q-axis component of the secondary current and outputs the vector difference as Δ̅I̅_{q-axis}.

The vector differences of the negative sequence current (Δ̅I̅_{negative}), the d-axis components (Δ̅I̅_{d-axis}), and the q-axis components (Δ̅I̅_{q-axis}) are the performance metrics. These performance metrics may be segregated into different bins as per their load unbalances since the performance metrics can vary depending on different unbalances in load. An unbalanced load is one in which the current is not the same in the three phases. The unbalance may be characterized by determining the average current in each phase, determining the largest deviation between the three average phase currents, and determining an unbalance metric by dividing the largest deviation by the average current. The unbalance metric may be expressed as an unbalance percentage by multiplying the unbalance metric by 100. The performance metrics may depend on the amount of unbalance, and the performance metrics may be segregated based on the amount of unbalance. For example, the performance metrics may be segregated into bins or intervals that each represent a 1% range of unbalance percentage. In this example, the bins would include 0-1%, greater than 1% to 2%, greater than 2% to 3%, and so on. Although the maximum amount of unbalance percentage is 100%, the unbalanced percentage is typically less than 10%, and the maximum unbalance percentage may be selected to reflect the maximum expected amount of unbalance. For example, if bins representing a range of 1% unbalance percentage were used and the maximum expected unbalance percentage was 10%, ten bins would be used to segregate the performance metrics. However, more or fewer bins may be used, and the bins may each represent a range of unbalance percentage other than 1% or may represent a range of unbalance metrics. Segregating the performance metrics by unbalance metric or unbalance percentage may result in improved data fitting at the fit estimation block 367.

The performance metrics and the per-unit load are provided to the fit estimation block 367. The per-unit load is the load normalized to the rated load. The per-unit load may be expressed as a percentage. For example, a per-unit load of 90% is a load that is 90% of the rated load. The fit estimation block 367 performs an analysis to determine a relationship between each performance metric and the per-unit load. For example, the fit estimation block 367 may perform a regression analysis to determine coefficients for each relationship. In some implementations, the fit estimation block 367 determines coefficients for a linear relationship between Δ̅I̅_{negative} and the per-unit load. In this example, the fit estimation block 367 determines the slope (m) and y-intercept (b) for the linear relationship having the form y=mx+b, where the negative sequence current differential (Δ̅I̅_{negative}) is plotted on the y axis, the per-unit load is plotted on the x axis, m is the slope of the linear relationship of the negative sequence differential as a function of per-unit load, and b is the y-axis intercept point (the value of the negative sequence current differential when the per-unit load is 0). The fit estimation block 367 also determines relationships between Δ̅I̅_{d-axis} and the per-unit load and between Δ̅I̅_{q-axis} and the per-unit load. In some implementations, the fit estimation block 367 fits the performance metrics to a non-linear equation, such as a second-order polynomial. The coefficients are determined during a training or commissioning phase and are stored on the electronic storage 254 for later use.

After the coefficients of the relationships are determined, the coefficients are used to determine estimated values for Δ̅I̅_{negative}, Δ̅I̅_{d-axis}, and Δ̅I̅_{q-axis} for one or more per-unit load values. The estimated values for Δ̅I̅_{negative}, Δ̅I̅_{d-axis}, and Δ̅I̅_{q-axis} are provided to the assessment block 368, which compares the estimate of a particular performance metric to the respective calculated value of that performance metric at a plurality of per-unit loads to determine how close the estimated value is to the calculated value. In other words, the assessment block 368 provides an indication of the accuracy of the relationship determined by the fit estimate block 367.

The assessment block 368 includes a sequence comparator 368_1, a d-axis comparator 368_2, and a q-axis comparator 368_3. The sequence comparator 368_1 determines a difference or error 369_1 between Δ̅I̅_{negative}, which is calculated based on measured data and is output from the symmetrical components calculation block 363, and the estimate of Δ̅I̅_{negative}, which is determined based on the relationship between the differential negative sequence current and per-unit load found by the fit estimation block 367. The d-axis comparator 368_2 determines a difference or error 369_2 between Δ̅I̅_{d-axis}, which is calculated based on measured data and is output from the transformation block 364, and the estimate of Δ̅I̅_{d-axis}, which is determined based on the relationship between the differential d-axis component as a function of per-unit load found by the fit estimation block 367. The q-axis comparator 368_3 determines a difference 369_3 or error between Δ̅I̅_{q-axis}, which is calculated based on measured data and is output from the transformation block 364, and the estimate of Δ̅I̅_{q-axis}, which is determined based on the relationship between the differential q-axis component as a function of per-unit load found by the fit estimation block 367.

The errors 369_1, 369_2, 369_3 are provided to the training block 370, which determines performance thresholds 371, 372, 373 for the transformer 210. The performance threshold 371 is a differential negative sequence threshold and is based on the error 369_1. The performance threshold 372 is a differential d-axis threshold and is based on the error 369_2. The performance threshold 373 is a differential q-axis threshold and is based on the error 369_3. The performance thresholds 371, 372, 373 are determined from the respective errors 369_1, 369_2, 369_3. For example, in implementations in which each of the errors 369_1, 369_2, 369_3 includes multiple values corresponding to many samples or time stamps, the largest absolute value is set as the respective performance threshold. The performance thresholds 371, 372, 373 are stored on the electronic storage 254 for later use.

The performance thresholds 371, 372, 373 are provided to the assessment block 380. The assessment block 380 applies the performance thresholds 371, 372, 373 to later-collected data to monitor the transformer 210 for potential failures. As discussed above, the performance thresholds 371, 372, 373 may be determined based on performance metrics that were segregated on the basis of the unbalance metric or the unbalance percentage. Also as discussed above, the performance metrics may be segregated based on bins that do not include all of the possible unbalance metric values or all of the possible unbalance percentages. In these implementations, when an unbalance metric value or unbalance percentage is encountered in the monitoring phase that was not encountered in the training phase, retraining is performed to obtain additional estimated values for the performance thresholds 371, 372, 373 using the fit estimation block 367. The assessment block 380 also then produces the electrical asset health indicator 258, which, in this example, includes information related to whether or not the transformer 210 includes a potential failure.

FIG. 4 is a flow chart of a process 400. The process 400 is an implementation of a training process that uses the commissioning block 360. The process 400 is discussed with respect to the transformer 210 and is used to determine the performance thresholds 371, 372, 373. However, the process 400 may be used with data from any three-phase electrical asset to determine performance thresholds for that three-phase electrical asset. The process 400 is performed when the transformer 210 is in a normal or healthy operating condition when no faults or potential failures are present in the transformer 210.

A moving average of a first AC electrical quantity (410_1) is determined and a moving average of a second AC electrical quantity (410_2) is determined. The first AC electrical quantity is sensed by the sensors 218A, 218B, 218C and the second AC electrical quantity is sensed by the sensors 219a, 219b, 219c. The first AC electrical quantity may be, for example, measurements of the AC current that flows in the nodes 215A, 215B, 215C. The second AC electrical quantity may be, for example, measurements of the AC current that flows in the nodes 216a, 216b, 216c. In the discussion below, the first AC electrical quantity is referred to as the primary current and the second AC electrical quantity is referred to as the secondary current. The moving averages are determined by the pre-conditioning block 361. As discussed above, the pre-conditioning block 361 produces a moving average of the primary current and a moving average of the secondary current. The process 400 may be implemented without (410_1) and (410_2).

The moving average of the primary current is provided to the compensation block 362 to produce Ip_ave_comp, which is a compensated average primary current (420_1). The moving average of the secondary current is provided to the compensation block 362 to produce Is_ave_comp, which is a compensated average secondary current (420_2).

A plurality of components are calculated for the first AC electrical quantity (430_1). The plurality of components are the negative sequence component, the d-axis component, and the q-axis component of the primary current. The compensated average primary current (Ip_ave_comp) is provided to the symmetrical components calculation block 363, which determines the negative sequence primary current (Ip_neg). The compensated average primary current (Ip_ave_comp) is also provided to the transformation block 364, which determines the d-axis component (Ip_d) and q-axis component (Ip_q) of the primary current.

These components are also calculated for the second AC electrical quantity (430_2). The plurality of components of the secondary current are the negative sequence component, the d-axis component, and the q-axis component. The compensated average secondary current (Is_ave_comp) is provided to the symmetrical components calculation block 363, which determines the negative sequence secondary current (Is_neg). The compensated average secondary current (Is_ave_comp) is also provided to the transformation block 364, which determines the d-axis component (Is_d) and q-axis component (Is_q) of the secondary current.

Performance metrics are calculated based on the calculated components (440). The performance metrics are differential components. Specifically, a differential negative sequence component (ΔIneg) is calculated by providing the negative sequence primary current (Ip_neg) and the negative sequence secondary current (Is_neg) to the comparator 365. A differential d-axis component (ΔId) is calculated by providing the d-axis component of the primary current (Ip_d) and the d-axis component of the secondary current (Is_d) to the comparator 366_d. A differential q-axis component (ΔIq) is calculated by providing the q-axis component of the primary current (Ip_q) and the q-axis component of the secondary current (Is_q) to the comparator 366_q.

The aspects of the process 400 from (410_1) and (410_2) through (440) are referred to as the data-gathering or commissioning stage 405. The data-gathering or commissioning stage 405 is a sub-process that receives the indications 213, 217 of the primary and secondary current from the transformer 210 (or other primary and secondary AC electrical data from a monitored three-phase electrical asset) and determines the performance metrics from that data as discussed above. Although the stage 405 is performed when the transformer 210 is in healthy operation in the process 400, the stage 405 is also used to analyze later-collected data when the transformer 210 may or may not be in a healthy condition.

The process 400 also includes a training stage, which includes (450) through (470). The training stage uses the performance metrics to determine performance thresholds that are specific to the transformer 210 (or other monitored three-phase electrical asset).

Performance coefficients are determined for each performance metric (450). The performance coefficients are determined by the fit estimation block 367, as discussed above with respect to FIG. 3. The coefficients define a relationship between the performance metric and a per-unit load of the transformer 210.

An estimated value of each performance metric is determined based on the performance coefficients for that performance metric (460). The estimated values of the performance metrics are referred to as (ΔIneg_est), (ΔId_est), and (Δq_est). As discussed above with respect to FIG. 3, the thresholds 371, 372, 373 are determined based on the errors 369_1, 369_2, 369_3, which are found by comparing the estimate of each performance metric to the calculated value of that performance metric.

The performance thresholds 371, 372, 373 may be determined by the manufacturer at the time of manufacturing the transformer 210 and stored on the electronic storage 254 by the manufacturer. For example, the manufacturer may determine the performance thresholds 371, 372, 373 using a laboratory or testing site at the manufacturing facility. In another example, the performance thresholds 371, 372, 373 are determined after the transformer 210 is installed and connected to the grid 201. Moreover, the training stage, which includes (450) through (470), may be repeated on a periodic basis (for example, hourly, daily, or weekly) when the transformer 210 is initially installed and connected to the grid 201. The performance thresholds 371, 372, 373 may change each time the training stage is repeated and may become more accurate for the transformer 210. In these implementations, the performance thresholds 371, 372, 373 may be considered to be dynamically determined.

Regardless of the circumstances of determining the performance thresholds 371, 372, 373, the performance thresholds 371, 372, 373 can be used to monitor the transformer 210 for potential failures without being updated or changed until one or more of the windings 212A, 212B, 212C, 212a, 212b, 212c are replaced.

The performance thresholds 371, 372, 373 are determined under normal or healthy operating conditions when a fault, failure, or potential failure is not present in the transformer 210. This allows the performance thresholds 371, 372, 373 to be used to assess later-collected data from the transformer 210 to determine whether a potential failure exists in the transformer 210.

FIG. 5 is a flow chart of a monitoring process 500. The monitoring process 500 is performed by the assessment block 380 (FIG. 3), which is part of the control scheme 257. The monitoring process 500 uses the performance thresholds 371, 372, 373 to monitor the transformer 210 for potential or early failures and is performed after the process 400. The assessment block 380 is implemented as a collection of executable instructions that are stored on the electronic storage 254 and executed by the electronic processing module 252. The process 500 is discussed with respect to the transformer 210 but may be used to monitor any three-phase electrical asset after performance thresholds are determined for that three-phase electrical asset. In the discussion below, the prime symbol (′) is used to indicate data or calculated values that are obtained during the monitoring process 500.

The indications 213′ and 217′ are provided to the data-gathering stage 405. As discussed above with respect to FIG. 4, the data-gathering stage 405 produces the performance metrics as discussed above. The performance metrics determined in the process 500 are as follows: a differential negative sequence component (ΔIneg′), a differential d-axis component (ΔId′), a differential q-axis component (ΔIq′).

A difference between each performance metric determined by the data-gathering stage 405 and a pre-determined estimate of that performance metric (580) is calculated to determine error metrics. The pre-determined estimate of the performance metrics are determined from the performance coefficients that were found in the process 400 at (450) and (460). The estimated performance metrics found at (460) are (ΔIneg_est), (ΔId_est), and (Δq_est). The differences or error metrics may be calculated as follows: error_neg′=(ΔIneg_est)−(ΔIneg′); error_d′=(ΔId_est)−(ΔId′); and error_q′=(ΔIq_est)−(ΔIq′). In some implementations, an absolute value of each difference or error metric is also calculated.

The calculated error metrics (error_neg′, error_d′, error_q′) are compared to the respective performance thresholds 371, 372, 373 (585). If the magnitude of the calculated error metric error_neg′ exceeds the threshold 371, then error_neg′ is considered to have exceed its respective threshold. Similarly, if the magnitude of error_d′ or error_q′ exceeds the threshold 372 or 373, respectively, then error_d′ or error_q′ exceeds its respective threshold. The calculated error metrics error_neg′, error_d′, error_q′ may be determined repeatedly over a period of time. In some implementations, the calculated error metric is only considered to exceed its respective performance threshold if the magnitude of the value of the calculated error metric exceeds the respective threshold for a pre-set amount of time or for a pre-set amount of samples.

If two or more of the calculated error metrics exceed the respective performance threshold, a potential failure, an early failure, a potential fault, or a failure or fault is present in the transformer 210 and the electrical asset health indicator 258 is updated to indicate that there is a fault or potential fault in the transformer 210 (585). If one or none of the calculated error metrics exceed the respective performance threshold, the process 500 returns to the start to continue monitoring the transformer 210, or the process 500 ends.

The electrical asset health indicator 258 may be calculated in other ways. Moreover, the electrical asset health indicator 258 is not necessarily a calculated value. For example, the electrical asset health indicator 258 may be manually entered into the I/O interface 256 based on observation of the transformer 210.

FIG. 6 is a block diagram of the fluid leak detection module 290. The fluid leak detection module 290 includes a temperature estimation block 691 that calculates an estimated temperature 695 of the fluid 246 at the location of the sensor 247t based on the measured data 255. The temperature estimate 695 also may be referred to as the “top oil” temperature estimate. The temperature estimation block 691 may be implemented based on the Institute of Electrical and Electronics Engineers (IEEE) C57.91 standard, as shown in Equations (14) and (15):

$${ΔΘ}_{T O} = {{ΔΘ}_{T O , R} [ \frac{( {K}_{U}^{2} R + 1 )}{( R + 1 )} ]}^{n} , \qquad Equation ( 14 )$$

where Δ_{TO} is the predicted change in the temperature 242t over a single time step when the transformer 210 is operated at a load factor K, Δ_{TO,R} is the change in the temperature 242t over the time step when the transformer is operated at the rated load, n is an empirically derived and pre-known constant associated with the transformer 210, and R is the ratio of load loss at rated load to no-load loss for the transformer 210. The temperature estimate 695 is the estimate of the temperature of the fluid 246 near the inlet 271 and is calculated based on the IEEE C57.91 standard, as shown in Equation (15):

$${Θ}_{T O} = {Θ}_{A} + {ΔΘ}_{T O} , \qquad Equation ( 15 )$$

where Θ_{TO} is the temperature estimate 695; Θ_{A} is the ambient temperature (as provided by the sensor 247a or forecasted weather data), and ΔΘ_{TO} is the fluid 246 temperature rise over ambient for a time step estimated by Equation (14).

The temperature estimate 695 is provided to a temperature error block 692 that determines a temperature difference or temperature error 697 between the top fluid temperature indication 242t (which is part of the measured data 255) and the temperature estimate 695. The temperature error 697 is provided to a fault analysis block 694 that determines a plurality of fault indicators 681 based on the temperature error 697.

The fault indicators 681 are provided to a feature analysis block 698 that determines features 682 of the fault indicators 681. The features 682 may be a reduced feature set that consumes less electronic memory and may be manipulated more easily than the fault indicators 681. The feature analysis block 698 may determine the features 682 using, for example, principle component analysis (PCA). In implementations in which the features 682 are determined based on PCA, the features 682 are one or more of the principle components.

The features 682 are provided to a classifier block 696. The classifier block 696 classifies the features 682 as being indicative of an abnormal or unexpected temperature rise (which can indicate that a fluid leak condition exists in the transformer 210) or as being indicative of a typical temperature variation (which indicates that there is no fluid leak condition in the transformer 210). The classifier block 696 outputs a health indicator 689 based on the determined classification of the features 682.

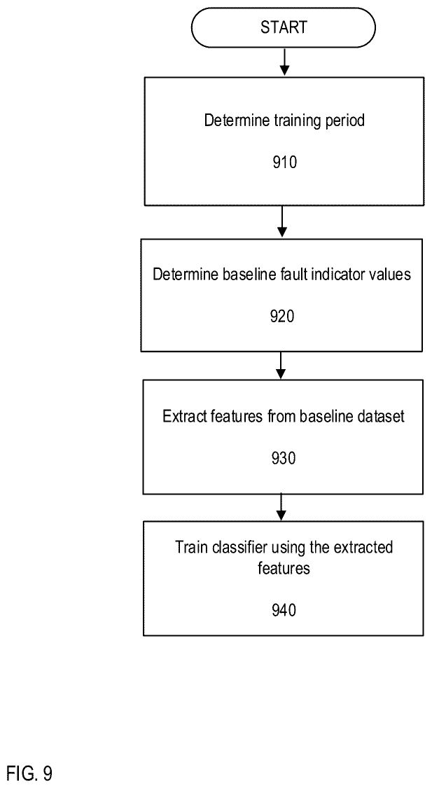

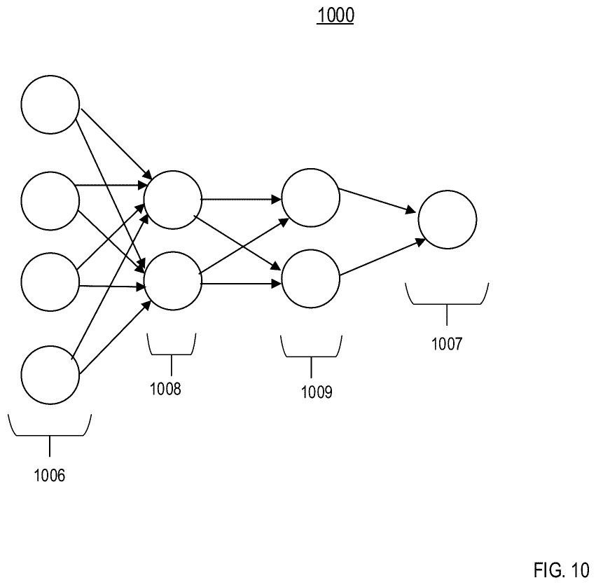

The classifier block 696 may be any kind of classifier that is capable of analyzing the features 682 and determining the health indicator 689 based on the features 682. For example, the classifier block 696 may implement a machine learning technique or an artificial neural network (ANN), such as the neural network 1000 shown in FIG. 10. The classifier block 696 may be trained on data from the transformer 210 or from historical data from another transformer, as discussed with respect to FIG. 9.

The health indicator 689 is a value or flag that represents a likelihood that a fluid leak condition exists in the transformer 210. The health indicator 689 may be a binary flag that has two possible values, for example, 1 or 0, or positive or negative. In this example, the health indicator 689 being equal to 1 or positive indicates that the transformer 210 is healthy and a fluid leak condition does not exist in the transformer 210. The health indicator 689 being equal to 0 or negative indicates that the transformer 210 is not healthy and a fluid leak condition possibly exists in the transformer 210. In some implementations, the health indicator 689 is a value that between a lower and upper bound. For example, the health indicator 689 may be a value between 0 and 1 and may represent the probability of a fluid leak condition existing in the transformer 210.

The health indicator 689 is provided to a decision block 699. The decision block 699 determines a fluid leak output 693 that indicates whether or not a fluid leak condition exists in the transformer 210 based on the health indicator 689. In some implementations, the electrical apparatus health status indicator 258 is also provided to the decision block 699. In these implementations, the decision block 699 determines the fluid leak output 693 based on the health indicator 689 and the electrical apparatus health status indicator 258.

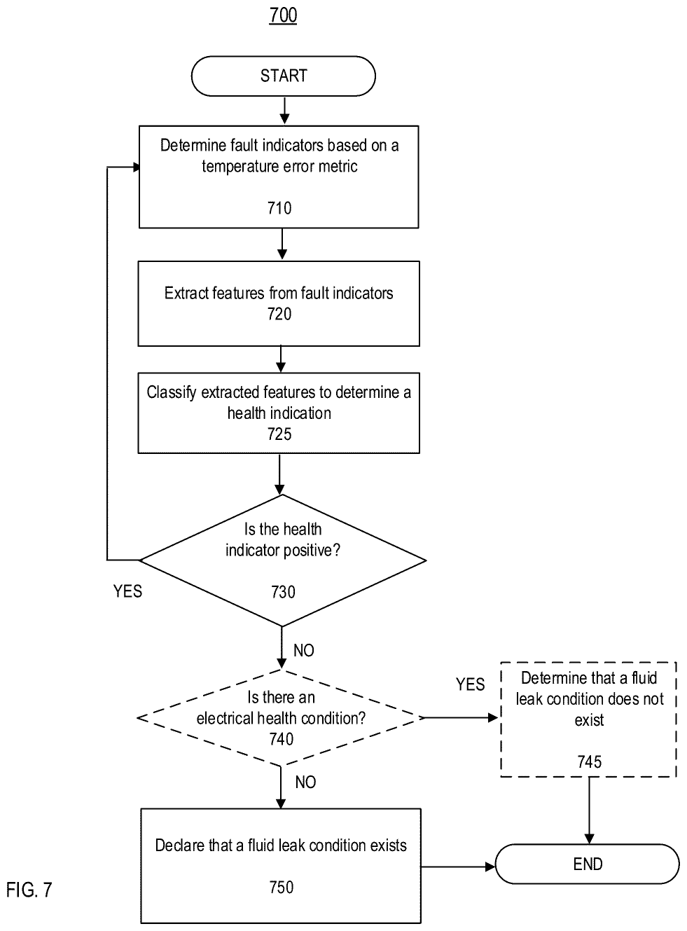

FIG. 7 is a flow chart of a process 700. The process 700 is an example of a process for determining whether the fluid 246 is leaking from the transformer 210. The process 700 may be performed by the electronic processing module 252 of the control system 250. The process 700 is discussed with respect to the leak detection module 290 and the transformer 210.

Fault indicators 681 are determined based on the temperature error 697 (710). The fluid 246 provides electrical and thermal insulation for the transformer 210. When the fluid 246 leaks from the transformer 210, the amount of fluid 246 in the interior 249 decreases, the temperature measured by the temperature sensor 247t increases by more than the predicted temperature increase ΔΘ_{TO}, and the discrepancy between the measured temperature of the fluid 246 and the temperature estimate 695 also increases. Thus, by monitoring the temperature error 697, potential leaks of the fluid 246 can be detected.

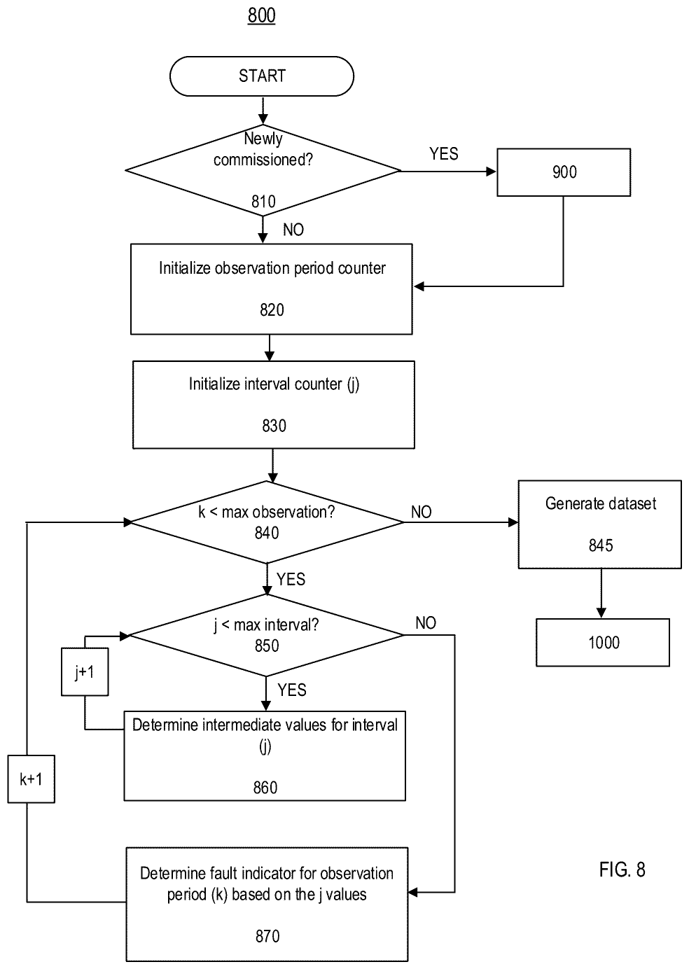

Any metric that includes or is based on the temperature error 697 may be used as a fault indicator. Examples of various metrics that may be used as the fault indicators 681 are discussed with respect to FIG. 8. As discussed with respect to FIG. 8, the process 800 generates an observation dataset (OD) that includes a value for each fault indicator 681 for each of M observations.

Features 682 are extracted from the fault indicators (720). The features may be extracted through any type of feature extraction process. For example, principle component analysis (PCA) may be applied to the observation dataset (OD) to extract the features 682.

The extracted features 682 are classified to determine the health indicator 689 (725). For example, the features 682 may be provided to the classifier block 696. The classifier block 696 analyzes the extracted features 682 and produces the health indicator 689, which is a predictor or indicator of whether or not a fluid leak condition exists in the transformer 210. The classifier block 696 implements a classifier that is trained based on data from the transformer 210 collected during a training period. FIG. 9 discusses an example of training the classifier.

If the health indicator 689 is positive at (730), a fluid leak condition does not exist in the transformer 210. The process 700 returns to (710) and continues to monitor the transformer 210 for a possible fluid leak by performing (710), (720), (725), (730).

If the health indicator 689 is negative at (730), a possible fluid leak exists in the transformer 210. The process 700 proceeds to (740) in implementations that use electrical health as a factor in determining whether there is a fluid leak in the transformer 210. The process 700 proceeds directly to (750) in implementations that do not use electrical health as a factor in determining whether there is a fluid leak in the transformer 210.

In implementations in which the electrical health of the transformer 210 is considered, when the health indicator 689 is negative at (730), the process 700 advances to (740) to determine whether or not an electrical health condition exists. A fluid leak causes the temperature error 697 to increase and the health indicator 689 may be used as the sole factor in declaring that a fluid leak exists. However, other failures in the transformer 210, such as shorts on the windings 212A, 212B, 212C, 212a, 212b, 212c also may cause the temperature error 697 to increase. Considering whether or not another type of malfunction is causing the increase in the temperature error 697 may increase the accuracy and reliability of the detection of a fluid leak and may conserve resources by pinpointing the cause of the fault more accurately.

In implementations that consider the electrical health of the transformer 210, the health status indicator 258, which is a value or a flag that indicates whether or not an electrical health condition exists, is used to determine whether or not an electrical health condition exists. If the health status indicator 258 indicates that there is an electrical failure or potential electrical failure, the increase in the temperature error 697 is likely not caused by the fluid 246 leaking from the transformer 210, and a fluid leak condition is determined to not exist (745). The process 700 ends, and repair on the electrical condition may begin, and/or the process 700 may return to (710) to continue monitoring the transformer 210.

If the health status indicator 258 indicates that there is no electrical failure or potential electrical failure in the transformer 210, the increase in the temperature error 697 is likely caused by the fluid 246 leaking from the transformer 210. A fluid leak condition is declared (750), and the fluid leak output 693 is set to a value that indicates the presence of a fluid leak in the transformer. The fluid leak output 693 may be presented to an operator visually, audibly, and/or electronically. The process 700 ends and/or returns to (710) to continue monitoring the transformer 210 while or before the repair process is initiated.

The process 700 may be implemented without using the health status indicator 258. In these implementations, if the health indicator 689 is negative at (730), the process 700 advances from (730) directly to (750) and sets the fluid leak output 693 to a value that indicates that a fluid leak exists in the transformer 210 without considering the health status indicator 258. Furthermore, in these implementations, the various calculations involved in determining the health status indicator 258 are not necessarily performed and may or may not be included on the electronic storage 254 of the control system 250. In other words, determination and/or use of the health status indicator 258 is optional for the control system 250. Furthermore, in some implementations, determination and use of the health status indicator 258 may be enabled or disabled by, for example, an operator, end user, or manufacturer of the transformer 210 or by the manufacturer.

FIG. 8 is a flow chart of a process 800 for generating the fault indicators 681. The process 800 is discussed with respect to the transformer 210 and the control system 250. However, the process 800 may be used to monitor other electrical apparatuses.

The transformer 210 is operated. The process 800 begins by determining if the transformer 210 is newly commissioned (810). The transformer 210 is considered newly commissioned if it has never been operated in the field or other setting in which it is installed and/or if no historical data exists for the transformer 210. If the transformer 210 is newly commissioned, the process invokes a training process 900, which is discussed below with respect to FIG. 9, and then proceeds to (820) after the training process 900 is complete.

If the transformer 210 is not newly commissioned, the process 800 begins to monitor the transformer 210 for a fluid leak condition while the transformer 210 operates. An observation period counter (k) is initialized (820). Initializing the observation period counter (k) includes setting a maximum number of observations (M, which is also the maximum value for k) and setting k to its initial value, which is 1. The maximum value of the observation period counter (M) is an integer number that is greater than or equal to 1 and represents the total number of observation periods that will be monitored. An interval counter (j) is initialized (830). Initializing the interval counter (j) includes setting j to its initial value, which is 1, and setting the number of intervals (N) in each observation period. For example, if each observation period is 24 hours, and each interval is an hour, the value of N is set to 24.

The fault indicators 681 are determined. In the example below, the fault indicators 681 are the root mean square error (RMSE) of the temperature error 697, the mean average error (MAE) of the temperature error 697, the median (MTE) of the temperature error 697, and the percent error (PE).

The current value of k is the initial value of k, which is less than the maximum value for the observation period counter (840), and the current value of j is the initial value of j, which is less than the maximum value for the interval counter (850). The process 800 advances to (860) to determine intermediate values in_1, in_2, in_3:

$$in\_ 1 ( j ) = \vert {T}_{247 t ( j )} - T\_est ( j ) \vert , \qquad Equation ( 16 )$$

where T_est(j) is the jth estimate of the temperature estimate 695 as calculated by Equation (15) and T_247t(j) is the measured temperature of the fluid 246 as measured by the sensor 247t at the time corresponding to the jth interval. For example, if j=1 and k=1, and the intervals are an hour, T_247t(j) is the temperature of the fluid 246 measured by the sensor 247t an hour after the initial observation period began. The intermediate value in_2 is determined:

$$in\_ 2 ( j ) = {[ \vert T\_est ( j ) - {T}_{247 t ( j )} \vert ]}^{2} , \qquad Equation ( 17 )$$

where T_est(j) and T_247t(j) are defined as above. The intermediate value in_3 is determined:

$$in\_ 3 ( j ) = \frac{\vert {T}_{247 t ( j )} - T\_est ( j ) \vert}{{T}_{247 t ( j )}} , \qquad Equation ( 18 )$$

where T_est(j) and T_247t(j) are defined as above.

The value of j is incremented by 1, and the process 800 returns to (850). The intermediate values in_1, in_2, in_3 are determined (860) for each of the N intervals, and j is incremented by 1 until j is equal to N. Thus, each of the intermediate values in_1, in_2, in_3 is an array that includes N values.

When the value of j is equal to N, the process 800 advances from (850) to (870) to determine the fault indicators 861 for the kth observation period. Continuing the example above, the current value of k is the initial value (1) and the fault indicators 681 are determined for the first observation period.

The values for the fault indicators 681 are determined as follows:

$$M A E ( k ) = \frac{{Σ}_{j = 1}^{N} in\_ 1 ( j )}{N} , \qquad Equation ( 19 )$$

where N is the number of intervals in the observation period;

$$R M S E ( k ) = \sqrt{\frac{{Σ}_{j = 1}^{N} in\_ 2 ( j )}{N}} ; \qquad Equation ( 20 )$$

$$M T E = median ( in\_ 1 ) , \qquad Equation ( 21 )$$

where median is the median operator and returns the value that is greater than half of the values in the array in_2. The median of the temperature error (MTE) for the kth observation period may be determined by sorting the N values in in_1 from lowest to highest. If N is an odd number, the median temperature error (MTE) is the temperature error value in the middle of the N sorted values. If N is an even number, the median temperature error (MTE) is the average of the two middle numbers in the N sorted list. The percent error (PE) for the kth observation period is determined by:

$$P E ( k ) = median ( in\_ 3 ) . \qquad Equation ( 22 )$$

After determining the fault indicators 681 for the kth interval, the value of k is incremented, and the process returns to (840). If the value of k is less than the maximum number of observations (M), the intermediate values in_1, in_2, in_3 are calculated for each interval in the next observation period (860), then the fault indicators 681 are calculated for the next observation period (870), and finally k is incremented again. This continues until the value of k is equal to the maximum number of observations (M). In this way, an observation dataset (OD) with M values for each of the fault indicators MAE, RMSE, MTE, and PE is provided (845). The observation dataset (OD) may be stored on the electronic storage 254 and/or provided to a separate process for further processing and/or analysis. For example, and returning to FIG. 7, the observation dataset (OD) may be used as the fault indicators 681 determined at (710).

Returning to (810), if the transformer 210 is newly commissioned, the training process (900) is invoked to train the classifier that is implemented by the classifier block 696. FIG. 9 is a flow chart of the training process 900. The training process 900 is performed during a training period that occurs when the transformer 210 is known to operate as expected and without electrical conditions or fluid leaks. By training the classifier with data collected during the training period, the classifier is able to recognize non-optimal or faulty performance (for example, fluid leaks) in data collected after the training period ends.

A training period is determined (910). The training period is a time period over which the transformer 210 is certain or very likely to perform as expected. The training period may be pre-defined and stored on the electronic storage 254 or entered into the control system 250 via the I/O interface 256. The training period may be defined as a temporal duration that begins at a specific time. For example, the training period may be a period of days, weeks, or a month after the transformer 210 is first installed.

Baseline values for the fault indicators 681 are determined during the training period (920). The values of the fault indicators 681 during the training period are determined using the same calculations as used to determine the values of the fault indicators during any other time period. For example, in implementations in which the fault indicators 681 include the median temperature error (MTE), the root mean square error (RMSE), the mean average error (MAE), and the percentage error (PE), a baseline dataset (BD) is generated for the baseline fault indicators using the process 800 (FIG. 8). The baseline dataset (BD) includes a value for each fault indicator at each observation time in the training period. For example, if the training period includes an observation every hour for a week, and the four fault indicators MTE, RMSE, MAE, and PE are calculated for each observation, the baseline dataset (BD) includes (4*24*7) or 672 values. The baseline dataset (BD) is an m×n matrix. Continuing the example above, the BD is a 4×168 matrix.

Features are extracted from the baseline dataset (930). The features may be extracted using principle component analysis (PCA). PCA reduces the baseline dataset (BD) into a smaller set of data. The smaller set of data includes principle components that are determined from the original values in the baseline dataset (BD). The principle components are new variables that are linear combinations of the original data in the baseline dataset (BD). The principle components are found by performing a single value decomposition on the baseline dataset (BD). Single value decomposition factorizes the baseline dataset (BD) into three matrices:

$$X = V Δ {W}^{T} , \qquad Equation ( 23 )$$

where X is the baseline dataset (BD), V are left singular vectors, W are right singular vectors, and Δ are singular values of BD. The principle components are provided by a Score matrix(S) considering only the first L largest singular values and their singular vectors:

$$S = X {W}_{L} , \qquad Equation ( 24 )$$

where X is the baseline dataset (BD), W are the right singular vectors of Equation (23), and L is a positive integer number that represents the number of principle components to extract. The dominant principle components are found from the Score matrix(S).

The classifier is trained using the extracted features (940). In implementations in which the features are determined from PCA, the L principle components found in the Score matrix(S) of Equation (24) are the features. The classifier may be an artificial neural network. In these implementations, the L principle components are provided to the artificial neural network, and the artificial neural network is trained using the L principle components. FIG. 10 shows an example of an artificial neural network 1000. The artificial neural network (ANN) 1000 includes an input layer 1006, an output layer 1009, and hidden layers 1007 and 1008 between the input layer 1006 and the output layer 1009. The value at the output layer 1009 is the output of the classifier (the health indicator 689 in this example). Each layer 1006, 1007, 1008, 1009 includes one or more nodes (represented by circles in FIG. 10). The neural network 1000 may include more or fewer than two hidden layers and more or fewer nodes than shown in FIG. 10.

The neural network 1000 is a computing system of interconnected nodes. The nodes of the input layer 1006 represent the input data. In this example, the input data is the L principle components found from the Score matrix. The value at each node in the first hidden layer 1007 is related to the value at the nodes in the input layer 1006 by a first weight and a first activation function. The value at each node in the second hidden layer 1008 is related to the value at the nodes in the first hidden layer 1007 by a second weight and a second activation function. The value at the output layer 1009 is related to the nodes in the second hidden layer 1008 by a third weight and a third activation function. The activation functions are typically non-linear functions that allow the neural network 1000 to learn or detect patterns in the input data. The first, second, and third weights are determined through the training process. Specifically, a back propagation technique is used with the features extracted at (930) as the inputs to train the neural network 1000 and determine the first, second, and third weights. The first, second, and third weights determined at (940) and the activation functions define the neural network 1000. The trained neural network 1000 is an example of a classifier that may be used as classifier block 696 to classify data collected after the training period ends.

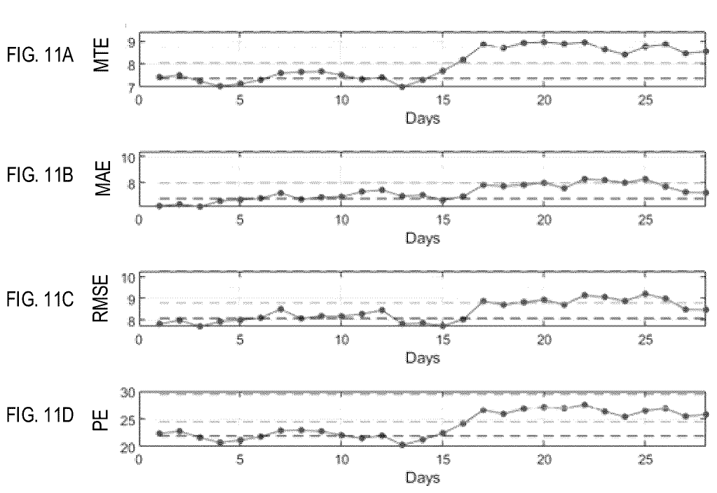

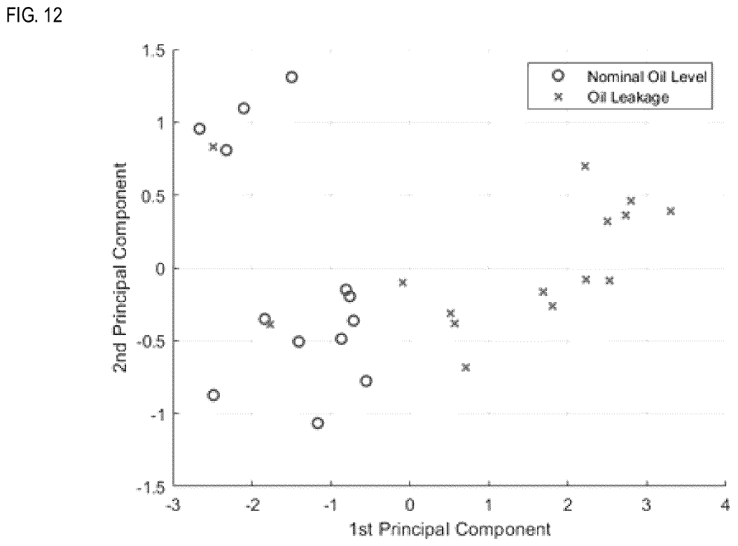

FIGS. 11A-11D and 12 relate to experimental test results. The test was performed with a 5 kVA transformer that had an oil volume capacity of 51 liters. To create an oil leakage scenario, 3.5 liters of the oil was removed from the 5 kVA transformer. Training data was collected for the healthy or baseline condition when there was 51 liters of oil in the transformer and observation data was collected after 3.5 liters of the oil (or 6.86% of the oil) was removed. The test was conducted at 50% to 100% load with a +/−2% variation in load and the ambient temperature varied between 21° C. and 25° C. Data was collected over 28 days. The fault indicators MTE, MAE, RMSE, and PE were determined as discussed above.

FIG. 11A is the fault indicator MTE as a function of days, FIG. 11B is the fault indicator MAE as a function of days, FIG. 11C is the fault indicator RMSE as a function of days, and FIG. 11D is the fault indicator PE as a function of days. The fault indicators MTE, MAE, RMSE, and PE were determined based on Equations (19) to (22) and as discussed above. FIGS. 11A-11D have the same x-axis and show the same time period. FIG. 12 is a scatter plot of the top two principle components determined from the data collected during the test.

In the test scenario, days 1 to 13 were a healthy condition, and days 14 to 28 had an oil leak condition. Referring to FIGS. 11A-11D, the values of each fault indicator increases beginning around day 15 due to the oil leak. Referring to FIG. 12, values of the first and second principle components determined from the data collected on days 1 to 13 (the healthy condition) are shown with the open circle symbol, and values of the first and second principle components determined from the data collected on days 14 to 28 (the fluid leak condition) are shown with the “x” symbol. As seen in FIG. 12, there is a fairly clear separation between the values associated with the healthy condition and the values associated with the fluid leak condition. The separation indicates that the first and second principle components may be used to by a classifier (such as the artificial neural network 1000) to classify later-occurring data as being collected during a healthy condition or during a fluid leak condition.

The technique discussed above uses a machine-learning based classifier block 696 to classify thermal data from a transformer as being indicative of an abnormal temperature rise or as being not indicative of an abnormal temperature rise. Because an abnormal temperature rise is a sign of a possible fluid leak, the machine-learning based classifier block 696 is also capable of detecting fluid leaks in transformers and other electrical devices that use a fluid-based thermal insulator. The machine-learning based classifier block 696 does not rely on fixed thresholds and is adaptable. This allows the machine-learning based classifier block 696 to be used with many devices at a site or in a fleet. Moreover, the machine-learning based classifier block 696 uses thermal data that is collected from existing sensors and other hardware devices. Thus, the machine-learning based classifier block may be retrofit into an existing apparatus and/or into an existing control system for an electrical apparatus without adding or replacing existing sensors.

These and other implementations are within the scope of the claims.

What is claimed is:

1. An electrical apparatus comprising:
a housing that defines an interior space configured to hold a fluid; and
a control system configured to:
obtain a measured temperature value of the fluid from a sensor;
build a dataset of fault indicator values, wherein each fault indicator is a numerical value based on a temperature error, the temperature error is based on a difference between the measured temperature value of the fluid and an estimated temperature value of the fluid;
generate one or more features from the dataset;
apply a classifier to the one or more features to determine a fluid leak output; and
determine whether a fluid leak condition exists in the electrical apparatus based on the fluid leak output.

2. The electrical apparatus of claim 1, wherein the control system is further configured to access an electrical apparatus health status indicator, and the control system is configured to determine whether the fluid leak condition exists based on the fluid leak output and the electrical apparatus health status indicator.

3. The electrical apparatus of claim 1, wherein the control system is configured to generate the one or more features from the dataset by applying a principle components analysis to the dataset, and the one or more features comprise one or more principle components of the fault indicator values of the dataset.

4. The electrical apparatus of claim 2, wherein the control system is configured to generate the one or more features from the dataset by applying a principle components analysis to the dataset, and the one or more features comprise one or more principle components of the fault indicator values of the dataset.

5. The electrical apparatus of claim 1, wherein the classifier comprises a machine learning model.

6. The electrical apparatus of claim 5, wherein the machine learning model comprises a neural network.

7. The electrical apparatus of claim 2, further comprising one or more electrical windings in the interior space, and wherein the control system determines that the fluid leak condition exists when one or more of the plurality of fault indicators does not meet the associated fault specification and the electrical health status indicator indicates that a short is not present in the one or more electrical windings.

8. The electrical apparatus of claim 2, further comprising one or more electrical windings in the interior space, and wherein the control system determines that the fluid leak condition does not exist when one or more of the plurality of fault indicators does not meet the associated fault specification and the electrical health status indicator indicates that a short is present in the one or more electrical windings.

9. The electrical apparatus of claim 1, wherein the plurality of fault indicators comprise: an average of the temperature error, a root mean square average of the temperature error, a mean average error of the temperature error, and a percent error of the temperature error.

10. The electrical apparatus of claim 1, wherein the measured temperature of the fluid comprises a temperature measurement of the fluid at fixed distance from a top of the interior space and the estimated temperature is an estimate of the temperature of the fluid at the same location.

11. The electrical apparatus of claim 1, wherein the electrical apparatus is a transformer.

12. A method for determining if a fluid leak condition exists in an electrical apparatus, the method comprising:
determining a temperature error based on a measured temperature of a fluid in the electrical apparatus and an estimated temperature of the fluid in the electrical apparatus;
determining fault indicators based on the temperature error;
extracting one or more features from the determined fault indicators;
providing the one or more features to a classifier to determine a value of a fluid health indicator;
analyze the value of the fluid health indicator to determine if a possible fluid leak condition exists; and
if a possible fluid leak condition exists:
determining whether an electrical fault condition exists,
if an electrical fault condition does not exist, determining that the possible fluid leak condition is an actual fluid leak condition, and
if an electrical fault condition exists, determining that no fluid leak condition exists.

13. The method of claim 12, wherein extracting one or more features from the determined fault indicators comprises performing principle component analysis on the fault indicators to extract one or more principle components.

14. The method of claim 12, further comprising training the classifier prior to providing the one or more features to the classifier.

15. A monitoring system for an electrical apparatus, the monitoring system comprising:
a temperature error module configured to determine a temperature error based on an estimated temperature of a fluid in an electrical apparatus and a measured temperature of the fluid in the electrical apparatus;
a fault analysis module configured to determine a plurality of fault indicators based on the temperature error;
a feature extraction block configured to determine a reduced dataset based on the plurality of fault indicators;
a classifier block configured to determine a fluid leak output based on the reduced dataset; and
a decision block configured to output a fluid leak indicator based on the fluid leak output.

16. The monitoring system of claim 15, wherein the decision block is configured to output the fluid leak indicator based on the fluid leak output and an electrical apparatus health status indicator, wherein the electrical apparatus health status indicator relates to the presence of an electrical fault in the electrical apparatus and the fluid leak output relates to the presence of a fluid leak in the electrical apparatus.
